(19) United States
(12) Patent Application Publication
(10) Pub. No.: US 2005/0147142 A1
(43) Pub. Date: Jul. 7, 2005

(54) Surface-emitting type semiconductor laser and method of manufacturing the same

(75) Inventors: Satoshi Kito, Suwa-shi (JP); Tsuyoshi Kaneko, Shimosuwa-machi (JP); Tsugio Ide, Nagato-machi (JP)

Correspondence Address: OLIFF & BERRIDGE, PLC, P.O. BOX 19928, ALEXANDRIA, VA, 22320, US

(73) Assignee: SEIKO EPSON CORPORATION, Tokyo (JP)

(21) Appl. No.: 10/980,329

(22) Filed: Nov. 4, 2004

(30) Foreign Application Priority Data
Nov. 18, 2003 (JP) 2003-388047

(51) Int. Cl. H01S 5/00; H01S 3/08

(52) U.S. Cl. 372/43

(57) ABSTRACT

A method is provided to provide surface-emitting type semiconductor lasers and methods for manufacturing the same, which can readily control transverse modes of laser light. A surface-emitting type semiconductor laser pertains to a surface-emitting type semiconductor laser having a vertical resonator above a substrate. The vertical resonator includes a first mirror, an active layer and a second mirror disposed in this order from the substrate, and is equipped with an optical path adjusting layer having a concave curved surface over the second mirror.

### CROSS-REFERENCE TO RELATED APPLICATION

The present application claims priority to Japanese Patent Application No. 2003-388047 filed Nov. 18, 2003, which is hereby expressly incorporated by reference.

### BACKGROUND OF THE INVENTION

1. Field of Invention

Exemplary aspects of the present invention relate to surface-emitting type semiconductor lasers and methods for manufacturing the same.

2. Description of Related Art

A surface emitting semiconductor laser is a semiconductor laser which emits laser light in a direction perpendicular to a semiconductor substrate. Since surface emitting type semiconductor lasers have excellent characteristics including, for example, easy handling, low threshold currents, etc., compared to edge emitting semiconductor lasers, application thereof to a variety of sensors and light sources for optical communications are expected. However, a related art surface-emitting type semiconductor laser has a polarization plane that is not stable, and would likely emit laser light in high-order transverse modes, because of the symmetry of its planar structure.

Therefore, when a surface-emitting type semiconductor laser is used for an optical system having polarization dependence, instability of polarization planes, specifically, instability of transverse modes of laser light, causes noise.

### SUMMARY OF THE INVENTION

Exemplary aspects of the present invention provide surface-emitting type semiconductor lasers and methods for manufacturing the same, which can readily control transverse modes of laser light.

A surface-emitting type semiconductor laser in accordance with exemplary aspect of the present invention pertains to a surface-emitting type semiconductor laser having a vertical resonator above a substrate.

The vertical resonator includes a first mirror, an active layer and a second mirror disposed in this order from the substrate, and is equipped with an optical path adjusting layer having a concave curved surface over the second mirror.

In the method of manufacturing a semiconductor device according to an exemplary aspect of the present invention, forming a specific layer (hereafter “B layer”) over another specific layer (hereafter “A layer”) includes a case in which the B layer is directly formed on the A layer, and a case in which B layer is formed over the A layer through another layer.

In the surface-emitting type semiconductor laser, since the vertical resonator has an optical path adjusting layer having a concave curved surface, transverse modes of laser light can be controlled for the following reasons. The angle of radiation of laser light of higher-order transverse modes is larger than that of laser light of the principal transverse mode. Therefore, the laser light of higher-order transverse modes is reflected by the concave curved surface. Thus the light is scattered, such that the loss becomes greater than the case where the light is reflected by a flat surface.

Specifically, the loss can be given to the laser light of higher-order transverse modes by the concave curved surface. As a result, the oscillation output of the laser light of a principal transverse mode relatively increases. Accordingly, the oscillation characteristics of the laser light become closer to those of the principal mode. In this manner, the transverse mode of the laser light can be controlled.

A surface-emitting type semiconductor laser in accordance with an exemplary aspect of the present invention pertains to a surface-emitting type semiconductor laser having a vertical resonator above a substrate. The vertical resonator includes a first mirror, an active layer and a second mirror disposed in this order from the substrate, and is equipped with an optical path adjusting layer having a concave curved surface below the first mirror.

By the surface-emitting type semiconductor laser, since the vertical resonator has the optical path adjusting layer having the concave curved surface, transverse modes of laser light can be controlled for the same reasons described above.

A method of manufacturing a surface-emitting type semiconductor laser in accordance with an exemplary aspect of the present invention pertains to a method of manufacturing a surface-emitting type semiconductor laser having a vertical resonator above a substrate, and includes stacking semiconductor layers to form at least a first mirror, an active layer and a second mirror over the substrate; forming a columnar section including at least a part of the second mirror by patterning the semiconductor layers; forming an insulation layer around the columnar section to form an embedding insulation layer; forming an electrode above the columnar section and the embedding insulating layer; forming a precursor layer over an emission surface of the columnar section, the electrode and the embedding insulation layer; forming a mask layer over the precursor layer; patterning the mask layer; forming a concave curved surface in the precursor layer by etching the precursor layer using the mask layer as a mask; and setting the precursor layer to form an optical path adjusting layer.

According to the method of manufacturing a surface-emitting type semiconductor laser, forming the optical path adjusting layer is added to a related art process of manufacturing a surface-emitting type semiconductor laser. For this reason, a surface-emitting type semiconductor laser in accordance with an exemplary aspect of the present invention can be manufactured by a relatively simple process.

A method of manufacturing a surface-emitting type semiconductor laser in accordance with an exemplary aspect of the present invention pertains to a method of manufacturing a surface-emitting type semiconductor laser having a vertical resonator above a substrate, and includes stacking semiconductor layers to form at least a first mirror, an active layer and a second mirror over the substrate; forming a columnar section including at least a part of the second mirror by patterning the semiconductor layers; forming an insulation layer around the columnar section to form an embedding insulation layer; forming an electrode above the columnar section and the embedding insulating layer; forming a concave section by etching a back surface of the semiconductor layers; embedding a precursor layer in the concave section; forming a mask layer below the precursor layer; patterning the mask layer; forming a concave curved surface in the precursor layer by etching the precursor layer using the mask layer as a mask; and setting the precursor layer to form an optical path adjusting layer.

According to the method of manufacturing a surface-emitting type semiconductor laser, forming the optical path adjusting layer is added to a related art process of manufacturing a surface-emitting type semiconductor laser. For this reason, a surface-emitting type semiconductor laser in accordance with an exemplary aspect of the present invention can be manufactured by a relatively simple process.

In the method of manufacturing a surface-emitting type semiconductor laser in accordance with an exemplary aspect of the present invention, the mask layer may be a liquid repelling film.

In the method of manufacturing a surface-emitting type semiconductor laser in accordance with an exemplary aspect of the present invention, the mask layer may be a resist layer.

In the method of manufacturing a surface-emitting type semiconductor laser in accordance with an exemplary aspect of the present invention, in etching the precursor layer, etchant can be dripped by a droplet discharging method.

### BRIEF DESCRIPTION OF THE DRAWINGS

FIG. 1 is a schematic of a surface-emitting laser in accordance with a first exemplary embodiment of the present invention;

FIG. 2 is a cross-sectional schematic of the surface-emitting laser shown in FIG. 1;

FIG. 3 is a cross-sectional schematic showing a method of manufacturing the surface-emitting laser in accordance with the first exemplary embodiment;

FIG. 4 is a cross-sectional schematic showing the method of manufacturing the surface-emitting laser in accordance with the first exemplary embodiment;

FIG. 5 is a cross-sectional schematic showing the method of manufacturing the surface-emitting laser in accordance with the first exemplary embodiment;

FIG. 6 is a cross-sectional schematic showing the method of manufacturing the surface-emitting laser in accordance with the first exemplary embodiment;

FIG. 7 is a cross-sectional schematic showing the method of manufacturing the surface-emitting laser in accordance with the first exemplary embodiment;

FIG. 8 is a cross-sectional schematic showing the method of manufacturing the surface-emitting laser in accordance with the first exemplary embodiment;

FIG. 9 is a cross-sectional schematic showing the method of manufacturing the surface-emitting laser in accordance with the first exemplary embodiment;

FIG. 10 is a cross-sectional schematic showing the method of manufacturing the surface-emitting laser in accordance with the first exemplary embodiment;

FIG. 11 is a cross-sectional schematic showing the method of manufacturing the surface-emitting laser in accordance with the first exemplary embodiment; and

FIG. 12 is a cross-sectional schematic of a surface-emitting laser in accordance with a second exemplary embodiment of the present invention.

### DETAILED DESCRIPTION OF EXEMPLARY EMBODIMENTS

Exemplary embodiments of the present invention are described below with reference to the accompanying drawings.

1. First Exemplary Embodiment

1-1. Device Structure

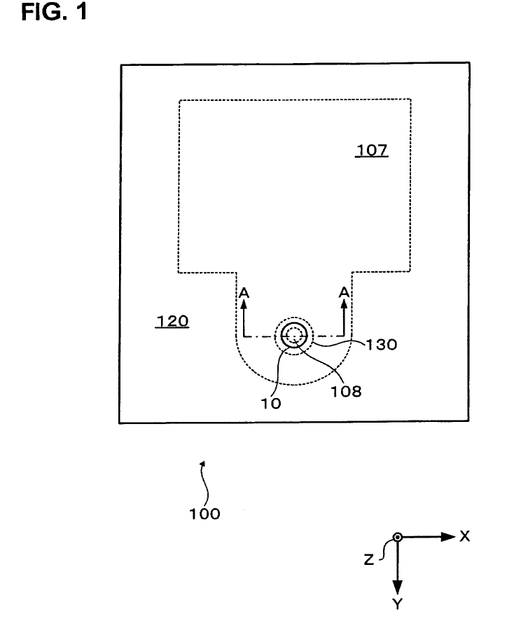

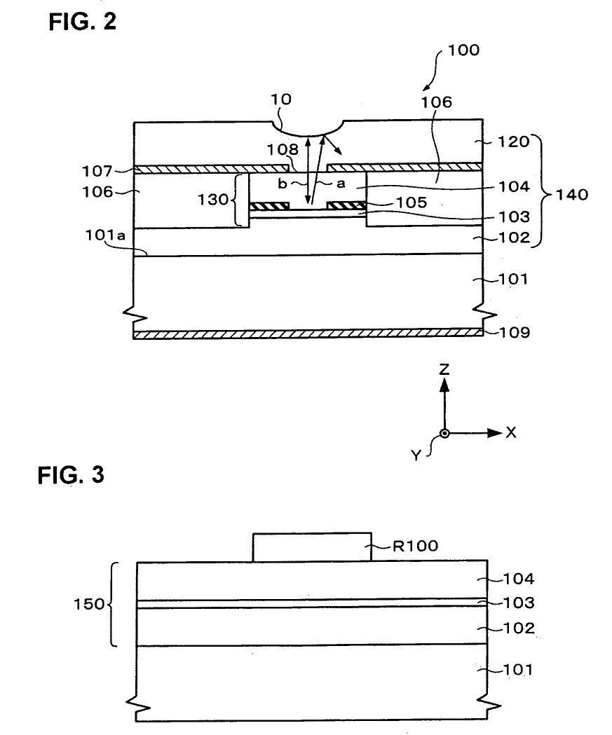

FIG. 1 is a schematic of a surface-emitting type semiconductor laser (hereinafter “surface emitting laser”) 100 in accordance with a first exemplary embodiment of the present invention. FIG. 2 is a schematic taken along a plane A-A of FIG. 1.

The surface emitting laser 100 according to the present exemplary embodiment includes, as shown in FIG. 1 and FIG. 2, a semiconductor substrate (a GaAs substrate in the present exemplary embodiment) 101, a vertical resonator (hereafter “resonator”) 140 formed on the semiconductor substrate 101, a first electrode 107 and a second electrode 109. The resonator 140 includes a first mirror 102, an active layer 103, a second mirror 104, and an optical path adjusting layer 120 including a concave curved surface 10.

Next, components of the surface-emitting laser 100 are described below.

The resonator 140 may be formed, for example, from the first mirror 102 that is a distributed reflection type multilayer mirror of forty pairs of alternately laminated n-type Al_{0.9}Ga_{0.1}As layers and n-type Al_{0.15}Ga_{0.85}As layers, the active layer 103 composed of GaAs well layers and Al_{0.3}Ga_{0.7}As barrier layers in which the well layers include a quantum well structure composed of three layers, and the second mirror 104 that is a distributed reflection type multilayer mirror of twenty five pairs of alternately laminated p-type Al_{0.9}Ga_{0.1}As layers and p-type Al_{0.15}Ga_{0.85}As layers. It is noted that the composition of each of the layers and the number of the layers forming the first mirror 102, the active layer 103 and the second mirror 104 are not limited to the above.

The resonator 140 further includes the optical path adjusting layer 120 having the concave curved surface 10. The optical path adjusting layer 120 is described in greater detail below.

The second mirror 104 is made to be p-type, for example, by doping C, Zn or Mg, and the first mirror 102 is made to be n-type, for example, by doping Si or Se. Accordingly, the second mirror 104, the active layer 103 in which no impurity is doped, and the first mirror 102, form a pin diode.

The second mirror 104, the active layer 103 and a part of the first mirror compose a semiconductor deposited body in a pillar shape (hereafter “columnar section”) 130. The side surface of the columnar section 130 is covered with an insulation layer 106.

An insulation layer 105, that functions as a current constricting layer, may be formed in a region among the layers composing the columnar section 130 near the active layer 103. The current constricting layer 105 can have a ring shape along the circumference of the columnar section 130. Also, the insulation layer 105 for current constriction is composed of aluminum oxide, for example.

The surface-emitting laser 100 of the present exemplary embodiment is provided with an embedding insulation layer 106 formed in a manner to cover a side wall of the columnar portion 130. A resin that composes the dielectric layer 106 may be polyimide resin, fluororesin, acrylic resin, or epoxy resin, and more particularly, it may preferably be polyimide resin or fluororesin in view of their good workability and dielectric property.

The first electrode 107 is formed on an upper surface of the columnar section 130 and the embedding insulation layer 106. An opening section in the first electrode 107 over the columnar section 130 defines an emission surface 108 of laser light. The first electrode 107 is formed from a stacked layered film of an alloy of Au and Zn, and Au, for example. Further, the second electrode 109 is formed on a back surface of the semiconductor substrate 101. The second electrode 109 is formed from a stacked layered film of an alloy of Au and Ge, and Au, for example. In the surface-emitting laser 100 shown in FIG. 1 and FIG. 2, the first electrode 107 connects to the second mirror 104 on the columnar section 130, and the second electrode 109 connects to the semiconductor substrate 101. An electrical current is injected in the active layer 103 through the first electrode 107 and the second electrode 109.

The materials to form the first and second electrodes 107 and 109 are not limited to those described above, and, for example, metals, such as Cr, Ti, Ni, Au or Pt and these alloys, etc. can be used depending on the requirements for adhesion enforcement, diffusion prevention or anti-oxidation, etc.

The optical path adjusting layer 120 forming the resonator 140 is formed on the emission surface 108 of the columnar section 130 and on the first electrode 107. The optical path adjusting layer 120 has a concave curved surface 10. The concave curved surface 10 of the optical path adjusting layer 120 is formed such that its center generally coincides with the center of the emission surface 108 as viewed in a plan view. By arranging the optical path adjusting layer 120 having such a concave curved surface 10, transverse modes of laser light can be controlled. Its reasons are described below.

1-2 Operation of Device

General operations of the surface-emitting type semiconductor laser 100 of the present exemplary embodiment are described below. It is noted that the following method to drive the surface-emitting type semiconductor laser 100 is described as an example, and various changes can be made without departing from the subject matter of the present invention.

When a voltage in a forward direction is applied to the pin diode by the first electrode 107 and the second electrode 109, recombination of electrons and holes occur in the active layer 103, thereby causing emission of light due to the recombination. Stimulated emission occurs during the period the generated light reciprocates between the second mirror 104 and the first mirror 102, whereby the light intensity is amplified. When the optical gain exceeds the optical loss, laser oscillation occurs, whereby laser light is emitted from the emission surface 108 that is present on the upper surface of the columnar section 130 in a direction perpendicular to the semiconductor substrate 101.

According to the surface-emitting type semiconductor laser 100 of the present exemplary embodiment, because the resonator 140 includes the optical path adjusting layer 120 having the concave curved surface 10, transverse modes of laser light can be controlled for the following reasons. As shown in FIG. 2, laser light of a high-order transverse mode (indicated by an arrow a) has a greater angle of radiation than that of laser light of a basic transverse mode (indicated by an arrow b). As a result, the laser light of a high-order transverse mode is reflected by the concave curved surface 10 and the light is diffused, such that the loss becomes greater than the case where the light is reflected by a flat surface. Specifically, a loss can be given to the laser light of a higher-order transverse mode by the concave curved surface 10. As a result, the oscillation output of the laser light of the principal transverse mode increases relatively. Accordingly, the oscillation characteristics of the laser light become closer to those of the principal mode. In this manner, the transverse mode of laser light can be controlled.

1-3 Device Manufacturing Method

Next, an example of a method of manufacturing the surface-emitting type semiconductor laser 100 in accordance with a first exemplary embodiment of the present invention is described with reference to FIG. 3 to FIG. 1. FIG. 3 to FIG. 11 are schematics showing the steps of the method of manufacturing the surface-emitting type semiconductor laser 100 according to the present exemplary embodiment shown in FIG. 1 and FIG. 2, each of which corresponds to the cross section shown in FIG. 2.

(1) First, on the surface of the semiconductor substrate 101 composed of n-type GaAs, a semiconductor multilayer film 150, shown in FIG. 3, is formed by epitaxial growth while modifying its composition. It is noted here that the semiconductor multilayer film 150 is formed from, for example, a first mirror 102 of forty pairs of alternately laminated n-type Al_{0.9}Ga_{0.1}As layers and n-type Al_{0.15}Ga_{0.85}As layers, an active layer 103 composed of GaAs well layers and Al_{0.3}Ga_{0.7}As barrier layers in which the well layers include a quantum well structure composed of three layers, and a second mirror 104 of twenty five pairs of alternately laminated p-type Al_{0.9}Ga_{0.1}As layers and p-type Al_{0.15}Ga_{0.85}As layers. These layers are successively stacked in layers on the semiconductor substrate 101 to thereby form the semiconductor multilayer film 150.

When growing the second mirror 104, at least one layer thereof adjacent to the active layer 103 is formed as an AlAs layer or an AlGaAs layer that is later oxidized and becomes an insulation layer for current constriction 105. The Al composition of the AlGaAs layer that is to become the insulation layer 105 is 0.95 or greater. Also, the uppermost surface layer of the second mirror 104 may be formed to have a high carrier density such that ohm contact can be readily made with an electrode (first electrode 107).

The temperature at which the epitaxial growth is conducted is appropriately decided depending on the growth method, the kind of raw material, the type of the semiconductor substrate 101, and the kind, thickness and carrier density of the semiconductor multilayer film 150 to be formed, and in general may be 450° C.-800° C. Also, the time required to conduct the epitaxial growth is appropriately decided just as dose the temperature. Also, a metal-organic chemical vapor deposition (MOVPE: Metal-Organic Vapor Phase Epitaxy) method, a MBE method (Molecular Beam Epitaxy) method or a LPE (Liquid Phase Epitaxy) method can be used as a method for the epitaxial growth.

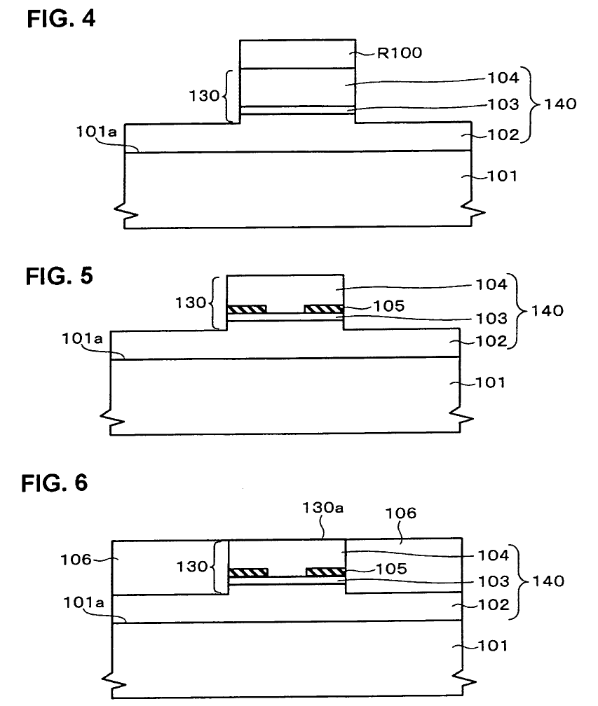

Next, resist is coated on the semiconductor multilayer film 150, and then the resist is patterned by a lithography method, thereby forming a resist layer R100 having a specified pattern, as shown in FIG. 3. The resist layer R100 is formed above an area where a columnar section 130 (see FIG. 1 and FIG. 2) is to be formed. Next, by using the resist layer R100 as a mask, the second mirror 104, the active layer 103, and a part of the first mirror 102 are etched by, for example, a dry etching method, thereby forming a semiconductor deposited body in a pillar shape (columnar section) 130, as shown in FIG. 4. Then, the resist layer R100 is removed.

Next, by placing the semiconductor substrate 101 on which the columnar section 130 is formed through the aforementioned steps in a water vapor atmosphere at about 400° C., for example, the layer having a high Al composition (a layer with an Al composition being 0.95 or higher) provided in the second mirror 104 is oxidized from its side surface, thereby forming an insulation layer for current constriction 105. The oxidation rate depends on the temperature of the furnace, the amount of water vapor supply, and the Al composition and the film thickness of the layer to be oxidized.

(2) Next, an embedding insulation layer 106 that surrounds the columnar section 130, specifically, a part of the first mirror 102, the active layer 103 and the second mirror 104, is formed (see FIG. 6).

Here, the case in which polyimide resin is used as a material to form the embedding insulation layer 106 is described. First, a precursor (polyimide precursor) is coated on the semiconductor substrate 101 having the columnar section 130 by using, for example, a spin coating method, to thereby form a precursor layer. In this instance, the precursor layer is formed such that its film thickness is greater than the height of the columnar section 130. As the method of forming the precursor layer, any one of techniques, such as, a dipping method, a spray coat method, an ink jet method or the like can be used, besides the aforementioned spin coating method.

Then, the semiconductor substrate 101 is heated by using, for example, a hot plate or the like, thereby removing the solvent. Then the precursor layer is imidized in the furnace at about 350° C., such that a polyimide resin that is almost completely set is formed. Next, as shown in FIG. 6, an upper surface 130a of the columnar section 130 is exposed, and the embedding insulation layer 106 is formed. As a method for exposing the upper surface 130a of the columnar section 130, a CMP method, a dry etching method, a wet etching method or the like can be used. Also, the embedding insulation layer 106 can be formed with a resin having photosensitivity. The embedding insulation layer 106 may be patterned depending on the requirements by a lithography method.

(3) Next, forming a first electrode 107 and a second electrode 109 to inject an electric current into the active layer 103, and an emission surface 108 of laser light (see FIG. 1 and FIG. 2) are described.

Prior to forming the first electrode 107 and the second electrode 109, an exposed upper surface of the columnar section 130 and the semiconductor substrate 101 may be washed by using a plasma treatment method, or the like, depending on the requirements. As a result, a device of more stable characteristics can be formed. Then, for example, a multilayer film of Au and an alloy of Au and Zn, is formed by, for example, a vacuum deposition method on the upper surface of the embedding insulation layer 106 and the columnar section 130, and then a portion where the multilayer film is not formed is formed on the upper surface of the columnar section 130 by a lift-off method. This portion becomes an emission surface 108. It is noted that, in the above step, a dry etching method or a wet etching method can be used instead of the lift-off method.

Also, a multilayer film of Au and an alloy of Au and Ge, for example, is formed by, for example, a vacuum deposition method on an exposed surface of the semiconductor substrate 101. Next, an annealing treatment is conducted. The temperature of the annealing treatment depends on the electrode material. This is usually conducted at about 400° C. for the electrode material used in the present exemplary embodiment. By the steps described above, the first electrode 107 and the second electrode 109 are formed.

(4) Next, forming an optical path adjusting layer 120 (see FIG. 1 and FIG. 2) composing the resonator 140 are described.

In accordance with the present exemplary embodiment, the optical path adjusting layer 120 may be formed with a material that does not absorb laser light to be emitted. Specifically, the optical path adjusting layer 120 may be formed with a material that does not have an absorption band in the wavelength band of laser light to be emitted from the surface-emitting laser 100. For the optical path adjusting layer 120, for example, polyimide resin, fluororesin, acrylic resin, epoxy resin, or the like can be used.

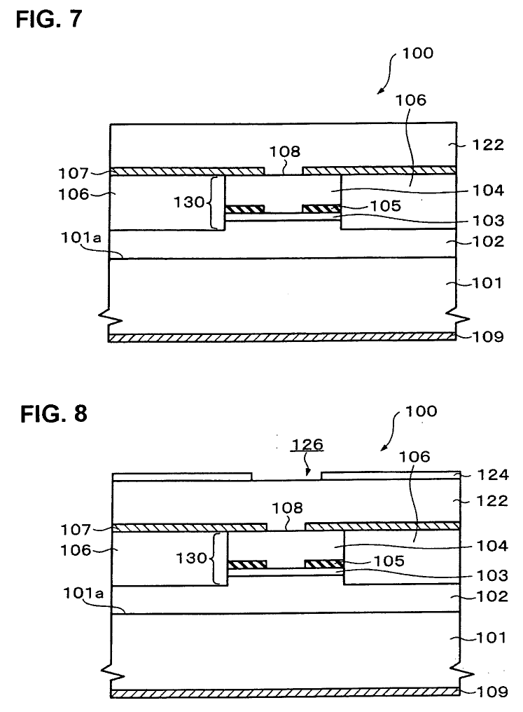

Here, the case in which polyimide resin is used as a material to form the optical path adjusting layer 120 is described. First, as shown in FIG. 7, a polyimide precursor layer 122 is formed in a manner to cover the columnar section 130 and the first electrode 107. As the method of forming the precursor layer 122, any one of techniques, such as, a spin coating method similar to the one used in forming the embedding insulation layer 106, a dipping method, a spray coat method, an ink jet method, or the like can be used.

Next, a mask layer 124 is formed in a region other than the region on the precursor layer 122 where the concave curved surface 10 (see FIG. 1 and FIG. 2) is formed. The mask layer 124 has a pattern that defines an opening in a portion corresponding to the concave curved surface 10, as shown in FIG. 1 and FIG. 2. Specifically, the pattern of the mask layer 124 of this example has a circular opening section 126 as viewed in a plan view. The central axis of the opening section 126 is formed to coincide with the central axis of the concave curved surface 10.

A resist layer can be used as the mask layer 124. When the resist layer is used as the mask layer 124, the mask layer 124 can be patterned by using a lithography technology.

Moreover, a repelling liquid film, such as, for example, a FAS (fluoroalkylsilane) film, or the like can be used as the mask layer 124. The repelling liquid film refers to a film having a liquid repelling property against etchant 20 to be described below. When FAS is used for the mask layer 124, for example, each of the following methods can be enumerated as a method of patterning the mask layer 124.

First, a resist layer is formed by using a lithography technique in a forming region of the opening section 126 of the mask layer 124. Next, the semiconductor substrate 101 on which the precursor layer 122 is formed is placed in an FAS gas atmosphere, to form a monomolecular film of FAS on an exposed surface of the precursor layer 122. Next, the resist layer is removed by using isopropyl alcohol (IPA), or the like. As a result, a monomolecular film of FAS having the opening section 126 (mask layer 124) is formed.

According to another method, first, the semiconductor substrate 101, on which the precursor layer 122 is formed, is placed in an FAS gas atmosphere, to form a monomolecular film of FAS on the surface of the precursor layer 122. Next, an ultraviolet ray is irradiated only to the forming region of the opening section 126 of the mask layer 124 through a glass mask or the like. As a result, the region of the monomolecular film of FAS where the ultraviolet ray is irradiated is resolved and removed, such that a monomolecular film of FAS having the opening section 126 (mask layer 124) is formed.

Next, by etching the precursor layer 122, the concave curved surface 10 (see FIG. 1 and FIG. 2) is formed. Specifically, the following is conducted.

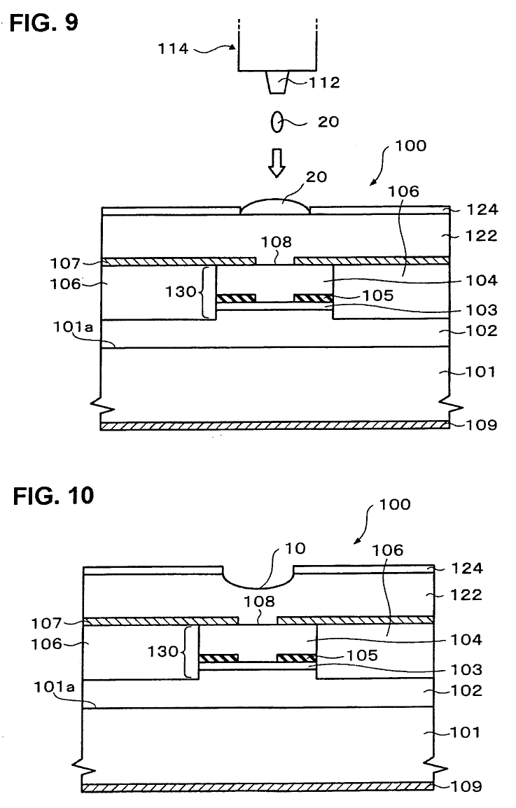

First, as shown in FIG. 9, etchant 20 is dropped to the opening section 126 (see FIG. 8) of the mask layer 124 by a droplet discharge method. As a result, the etchant 20 wets and spreads in a region surrounded by the mask layer 124, specifically, in the opening 126 of the mask layer 124. Then, the precursor layer 122 is isotropically etched by the etchant 20, whereby the concave curved surface 10 is formed in the precursor layer 122, as shown in FIG. 10.

As the method of discharging droplets, for example, (I) a method in which the size of a bubble in liquid (etchant 20 in here) is changed by heat to cause pressure, to thereby jet the liquid from an ink jet nozzle, (II) a method in which liquid is jetted from an ink jet nozzle by a pressure caused by a piezoelectric element, etc. can be enumerated. The method (II) may be preferred in view of pressure controllability.

The position of a nozzle 112 of an ink jet head 114 and the discharge position of the etchant 20 are aligned by the image recognition technology used in an exposure process and an examination process in an ordinary process for manufacturing semiconductor integrated circuits. For example, as shown in FIG. 9, alignment of the position of the nozzle 112 of the ink jet head 114 and the opening section 126 of the mask layer 124 (see FIG. 8) is done by image recognition. After alignment, the voltage to be impressed to the ink jet head 114 is controlled, and then the etchant 20 is discharged.

In this case, the discharge angle of the etchant 20 discharged from the nozzle 112 may have some variations. However, if the position where the etchant 20 hits is inside the opening section 126, the etchant 20 wets and spreads in the region encircled by the mask layer 124, and the position is automatically corrected.

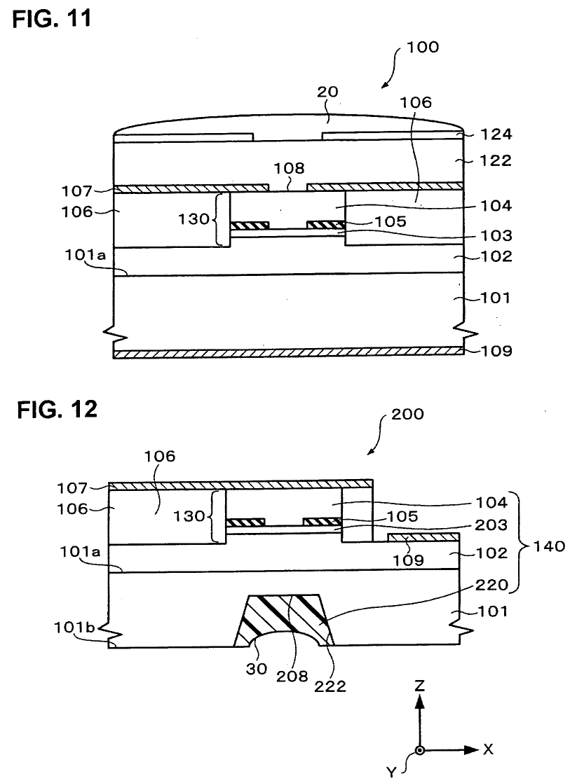

The method to etch the precursor layer 122 is not particularly limited to the droplet discharge method described above. But any one of the methods that can form the concave curved surface 10 in the precursor layer 122 can be used. For example, a method in which the semiconductor substrate 101 is soaked in the etchant 20 as shown in FIG. 11, and the precursor layer 122 is etched can also be used.

An etchant, that can etch the precursor layer 122, can be used as the etchant 20. For example, when the precursor layer 122 is a polyimide resin precursor, an alkaline developer, etc. can be used.

Next, the mask layer 124 is removed depending on the requirements. When, for example, a resist layer is used as the mask layer 124, the mask layer 124 can be removed by ashing. When, for example, a monomolecular film of FAS is used as the mask layer 124, it can be resolved and removed by irradiation of ultraviolet rays.

Next, after the surface of the precursor layer 122 is washed, the semiconductor substrate 101 is heated by using a hot plate or in a furnace, thereby supplying heat to the precursor layer 122 to set (imidize) the precursor layer, whereby the optical path adjusting layer 120 shown in FIG. 1 and FIG. 2 is formed.

By the process described above, the surface-emitting type semiconductor laser 100 shown in FIG. 1 and FIG. 2 can be obtained.

1-4. Functions and Effect

Main functions and effect of the present exemplary embodiment are described below.

In the surface-emitting laser 100 in accordance with the present embodiment, due to the fact that the vertical resonator 140 has the optical path adjusting layer 120 having the concave curved surface 100, transverse modes of laser light can be controlled for the following reasons. As shown in FIG. 2, laser light of a high-order transverse mode (indicated by an arrow a) has a greater angle of radiation than that of laser light of a principle transverse mode (indicated by an arrow b). As a result, the laser light of a high-order transverse mode is reflected by the concave curved surface 10 and the light is diffused, such that the loss becomes greater than the case where the light is reflected by a flat surface. Specifically, a loss can be given to the laser light of a higher-order transverse mode by the concave curved surface 10. As a result, the oscillation output of the laser light of the principal transverse mode increases relatively. Accordingly, the oscillation characteristics of the laser light become closer to those of the principal mode. In this manner, the transverse mode of laser light can be controlled.

By the surface-emitting laser 100 in accordance with the present exemplary embodiment, transverse modes of laser beam can be controlled as described above only by forming the optical path adjustment layer 120 above a related art surface-emitting laser. In other words, the structure of a related art surface-emitting laser can be used as it is.

According to the method of manufacturing a surface-emitting laser in accordance with the present exemplary embodiment, forming the optical path adjusting layer 120 is added to a related art process of manufacturing a surface-emitting laser. For this reason, a surface-emitting laser of an exemplary aspect of the present invention can be manufactured by a relatively simple process.

2. Second Exemplary Embodiment

2-1 Device Structure

FIG. 12 is a schematic of a surface-emitting type semiconductor laser 200 in accordance with a second exemplary embodiment of the present invention. It is noted that the same reference numerals are appended to components that are substantially the same as those of the surface-emitting type semiconductor laser 100 in accordance with the first exemplary embodiment, and their detailed description is omitted.

The surface-emitting laser 200 in accordance with the present exemplary embodiment has a structure different from that of the surface-emitting laser 100 of the first exemplary embodiment in that light emits from a back side 101b of a semiconductor substrate 101, a concave section 222 is disposed in the back surface 101b of the semiconductor substrate 101, an optical path adjusting layer 220 is embedded in the concave section 222, a second electrode 109 is formed on the same side of the semiconductor substrate 101 where a first electrode 107 is formed, and an emission surface 208 is provided on an upper surface of the optical path adjusting layer 220.

In the surface-emitting laser 200 in accordance with the present exemplary embodiment, the concave section 222 is formed in the back surface 101b of the semiconductor substrate 101, and the optical path adjusting layer 220 is embedded in the concave section 222. The width and film thickness of the optical path adjusting layer 220 can be controlled by adjusting the width and depth of the concave section 222.

Also, in the surface-emitting laser 200, an active layer 203 including InGaAs layers is formed. Therefore it has a structure different from that of the surface-emitting laser 100 of the first exemplary embodiment in which the active layer 103 including AlGaAs layers is formed. Specifically, the active layer 203 has a quantum wall structure including In_{0.3}Ga_{0.7}As well layers and GaAs barrier layers.

2-2 Operation of Device

Operations of the surface-emitting laser 200 of the present exemplary embodiment are basically the same as those of the surface-emitting laser 100 of the first exemplary embodiment. However, in the surface-emitting laser 200 of the present exemplary embodiment, the emission surface 208 is provided on the side of the back side 101b of the semiconductor substrate 101, such that light generated by the active layer 203 passes the lower mirror 102 and the semiconductor substrate 101, goes out from the emission surface 208, and then enters the optical path adjusting layer 220. The laser light that has entered the optical path adjusting layer 220 is emitted in a direction perpendicular to the semiconductor substrate 101 (Z direction indicated in FIG. 12) after transverse modes of the laser light have been controlled by the concave curved surface 20.

Also, the surface-emitting laser 200 can function as a surface-emitting laser that emits light with a wavelength of 880 nm or greater (for example, about 1100 nm) which is transmissible to the GaAs substrate, due to the fact that the active layer 203 including InGaAs layers is provided.

2-3 Device Manufacturing Method

Next, an example of a method of manufacturing the surface-emitting type semiconductor laser 200 in accordance with a second exemplary embodiment of the present invention is described.

The surface-emitting laser 200 of the second exemplary embodiment can be formed by steps generally similar to those of the process for manufacturing the surface-emitting laser 100 in accordance with the first exemplary embodiment up to halfway through the manufacturing process. Specifically, it is formed by the steps generally the same as those of the process of manufacturing the surface-emitting laser 100 in accordance with the first exemplary embodiment except that an active layer 203 including In_{0.3}Ga_{0.7}As well layers and GaAs barrier layers is formed instead of the active layer 103 (see FIG. 2), the planar configurations of first and second electrodes 107 and 109 are different, the first electrode 107 and the second electrode 109 are formed on the same side with respect to the semiconductor substrate 101, a concave section 222 is formed in a back surface 101b of the semiconductor substrate 101, and an optical path adjusting layer 220 having a concave curved surface 30 is formed in the concave section 222. Accordingly, features that are different from the process for manufacturing the surface-emitting laser 100 in accordance with the first exemplary embodiment are mainly described below.

Specifically, the process for manufacturing the surface-emitting laser 200 in accordance with the present exemplary embodiment is generally the same as the process for manufacturing the surface-emitting laser 100 of the first exemplary embodiment up to the point where an embedding insulation layer 106 is formed.

Then, the embedding insulation layer 106 that is present to the side of the second mirror 104 is removed, to expose the first mirror 102 (see FIG. 12). The embedding insulation layer 106 can be removed by etching that uses, for example, a lithography technique. For example, the etching can be conducted by a wet etching method, a dry etching method, or the like.

Next, a first electrode 107 is formed by, for example, a vacuum deposition method on an upper surface of the insulation layer 106 and the columnar section 130. Also, a second electrode 109 is formed on the upper surface where the first mirror 102 is exposed. The concrete method of forming the first and second electrodes 107 and 109 is the same as the method described in the first exemplary embodiment.

Next, a concave section 222 is formed in a back surface 101b of the semiconductor substrate 101. The concave section 222 can be formed by etching that uses, for example, a lithography technique. For example, the etching can be conducted by a wet etching method, a dry etching method, or the like.

Next, an optical path adjusting layer 220 having a concave curved surface 20 is embedded in the concave section 222. The concrete method to form the optical path adjusting layer 220 having the concave curved surface 20 is the same as the method described in the first exemplary embodiment.

By the process described above, the surface-emitting type semiconductor laser 200 shown in FIG. 12 can be obtained.

2-4. Functions and Effect

The surface-emitting laser 200 and its manufacturing method in accordance with the present exemplary embodiment provide substantially the same functions and effect obtained by the surface-emitting laser 100 and its manufacturing method in accordance with the first exemplary embodiment.

Although preferred exemplary embodiments of the present invention are described above, the present exemplary invention is not limited to these embodiments, and many modifications can be made. For example, in the first exemplary embodiment of the present invention described above, the description was made as to a two-face electrode structure in which the first electrode 107 is formed on the upper surface of the second mirror 104, and the second electrode 109 is formed on the back surface of the semiconductor substrate 101. However, a one-face electrode structure in which the first electrode 107 is formed on the upper surface of the second mirror 104 and the second electrode 109 is formed on the upper surface of the first mirror 102 can also be made.

For example, in the exemplary embodiments described above, a surface-emitting laser having one columnar portion is described. However, a plurality of columnar sections can be provided in a substrate surface. Also, similar functions and effects are obtained even when a plurality of surface-emitting lasers are provided in an array.

Also, it should be noted that, for example, interchanging the p-type and n-type characteristics of each of the semiconductor layers in the above described exemplary embodiments does not deviate from the subject matter of the present invention. In the above described first exemplary embodiment, the description is made as to an AlGaAs type, and in the above described second exemplary embodiment, the description is made as to an InGaAs type, but depending on the oscillation wavelength, other materials, such as, for example, GaInP type, ZnSSe type, InGaN type, AlGaN type, GaInNAs type, GaAsSb type, and like semiconductor materials can be used.

1. A surface-emitting type semiconductor laser, comprising:
a substrate;
a vertical resonator above the substrate, the vertical resonator including a first mirror, an active layer and a second mirror disposed in this order from the substrate, and an optical path adjusting layer having a concave curved surface over the second mirror.

2. A surface-emitting type semiconductor laser, comprising
a substrate;
a vertical resonator above the substrate, the vertical resonator including a first mirror, an active layer and a second mirror disposed in this order from the substrate, and an optical path adjusting layer having a concave curved surface below the first mirror.

3. A method of manufacturing a surface-emitting type semiconductor laser having a vertical resonator above a substrate, comprising:
stacking semiconductor layers to form at least a first mirror, an active layer and a second mirror over the substrate;
forming an electrode above the stacking semiconductor layers;
forming a precursor layer over an emission surface of the stacking semiconductor layers and the electrode;
forming a mask layer over the precursor layer;
patterning the mask layer;
forming a concave curved surface in the precursor layer by etching the precursor layer using the mask layer as a mask; and
setting the precursor layer to form an optical path adjusting layer.

4. The method of manufacturing a surface-emitting type semiconductor laser according to claim 3, the mask layer being a liquid repelling film.

5. The method of manufacturing a surface-emitting type semiconductor laser according to claim 3, the mask layer being a resist layer.

6. The method of manufacturing a surface-emitting type semiconductor laser according to claim 3, in etching the precursor layer, etchant being dripped by a droplet discharging method.

7. A method of manufacturing a surface-emitting type semiconductor laser having a vertical resonator above a substrate, comprising:
stacking semiconductor layers to form at least a first mirror, an active layer and a second mirror over the substrate, comprising;
forming an electrode above the stacking semiconductor layers;
forming a concave section by etching a back surface of the semiconductor layers;
embedding a precursor layer in the concave section;
forming a mask layer below the precursor layer;
patterning the mask layer;
forming a concave curved surface in the precursor layer by etching the precursor layer using the mask layer as a mask; and
setting the precursor layer to form an optical path adjusting layer.

8. The method of manufacturing a surface-emitting type semiconductor laser according to claim 7, the mask layer being a liquid repelling film.

9. The method of manufacturing a surface-emitting type semiconductor laser according to claim 7, the mask layer being a resist layer.

10. The method of manufacturing a surface-emitting type semiconductor laser according to claim 7, in the etching the precursor layer, etchant being dripped by a droplet discharging method.

11. The method of manufacturing a surface-emitting type semiconductor laser according to claim 4, the liquid repelling film being fluoroalkylsilane.

12. The method of manufacturing a surface-emitting type semiconductor laser according to claim 3, the precursor layer being isotropically etched.

13. The method of manufacturing a surface-emitting type semiconductor laser according to claim 3, in the patterning the mask layer, a pattern of the mask layer having a circular opening section.

14. The method of manufacturing a surface-emitting type semiconductor laser according to claim 13, a center of the opening section generally coinciding with a center of the emission surface.

15. The method of manufacturing a surface-emitting type semiconductor laser according to claim 3, a center of the concave curved surface generally coinciding with a center of the emission surface.

16. The method of manufacturing a surface-emitting type semiconductor laser according to claim 3, the optical path adjusting layer does not absorb an emitting light from the active layer.

17. The method of manufacturing a surface-emitting type semiconductor laser according to claim 3, the optical path adjusting layer being one of polyimide resin, fluororesin, acrylic resin and epoxy resin.
